(19) United States
(12) Patent Application Publication
(10) Pub. No.: US 2024/0324216 A1
(43) Pub. Date: Sep. 26, 2024

(54) SEMICONDUCTOR MEMORY DEVICE

(71) Applicant: Kioxia Corporation, Tokyo (JP)

(72) Inventors: Hiroyuki YAMASAKI, Nagoya Aichi (JP); Masayoshi TAGAMI, Kuwana Mie (JP); Katsuaki ISOBE, Yokohama Kanagawa (JP)

(73) Assignee: Kioxia Corporation, Tokyo (JP)

(21) Appl. No.: 18/597,150

(22) Filed: Mar. 6, 2024

(30) Foreign Application Priority Data
Mar. 23, 2023 (JP) 2023-046145

(51) Int. Cl. H10B 43/27; H01L 25/065; H10B 43/10; H10B 43/35; H10B 43/40

(52) U.S. Cl. CPC H10B 43/27; H01L 25/0657; H10B 43/10; H10B 43/35; H10B 43/40

(57) ABSTRACT

According to one embodiment, in a semiconductor memory device including a first chip and a second chip. The first chip includes a first stacked body, a first semiconductor film, a second stacked body, a second semiconductor film, a contact plug and a first planar wiring line. The contact plug extends in the third direction between the first stacked body and the second stacked body. The first planar wiring line is disposed on a side opposite to the second chip with respect to the first stacked body, the contact plug, and the second stacked body, the first planar wiring line extending in the first direction and the second direction, covering at least the contact plug, and being connected to the contact plug.

### CROSS-REFERENCE TO RELATED APPLICATIONS

This application is based upon and claims the benefit of Japanese Patent Application No. 2023-046145, filed on Mar. 23, 2023; the entire contents of which are incorporated herein by reference.

### FIELD

Embodiments described herein relate generally to a semiconductor memory device.

### BACKGROUND

A semiconductor memory device may be formed with a plurality of chips bonded to each other. The semiconductor memory device needs to have an appropriate layout in the chip located at an uppermost portion.

### BRIEF DESCRIPTION OF THE DRAWINGS

FIG. 1 is a block diagram illustrating a configuration of a semiconductor memory device according to a first embodiment;

FIG. 2 is a circuit diagram illustrating a configuration of a block in the first embodiment;

FIG. 3 is a plan view illustrating a schematic configuration of the semiconductor memory device according to the first embodiment;

FIG. 4 is a cross-sectional view illustrating a configuration of the semiconductor memory device according to the first embodiment;

FIGS. 5A and 5B are cross-sectional views illustrating a configuration of a memory cell according to the first embodiment;

FIG. 6 is a plan view illustrating a configuration of the semiconductor memory device according to the first embodiment;

FIG. 7 is a cross-sectional view illustrating a configuration of a division pattern according to the first embodiment;

FIG. 8 is a cross-sectional view illustrating a configuration of a division pattern according to the first embodiment;

FIG. 9 is a cross-sectional view illustrating a configuration of a division pattern according to the first embodiment;

FIG. 10 is a cross-sectional view illustrating a configuration of a connection portion of a planar wiring line to a cell source portion in the first embodiment;

FIG. 11 is a plan view illustrating a configuration of a semiconductor memory device according to a second embodiment ;

FIG. 12 is a plan view illustrating a configuration of a semiconductor memory device according to a third embodiment; and

FIG. 13 is a plan view illustrating the configuration of a semiconductor memory device according to a fourth embodiment.

### DETAILED DESCRIPTION

In general, according to one embodiment, there is provided a semiconductor memory device including a first chip and a second chip. The first chip extends in a first direction and a second direction intersecting the first direction. The second chip extends in the first direction and the second direction and bonded to the first chip in a third direction intersecting the first direction and the second direction. The first chip includes a first stacked body, a first semiconductor film, a second stacked body, a second semiconductor film, a contact plug and a first planar wiring line. The first stacked body includes a stack of a plurality of first conductive layers, each of the first conductive layers being stacked on each other via a first insulating layer. The first semiconductor film extends in the third direction within the first stacked body. The second stacked body is adjacent to the first stacked body in the second direction and has a stack of a plurality of second conductive layers, each of the second conductive layers being stacked on each other via a second insulating layer. The second semiconductor film extends in the third direction within the second stacked body. The contact plug extends in the third direction between the first stacked body and the second stacked body. The first planar wiring line is disposed on a side opposite to the second chip with respect to the first stacked body, the contact plug, and the second stacked body, the first planar wiring line extending in the first direction and the second direction, covering at least the contact plug, and being connected to the contact plug.

Exemplary embodiments of a semiconductor memory device will be explained below in detail with reference to the accompanying drawings. The present invention is not limited to the following embodiments.

### First Embodiment

The semiconductor memory device according to the first embodiment is formed with a plurality of chips bonded to each other, with techniques for providing an appropriate layout within the chip located at the uppermost position.

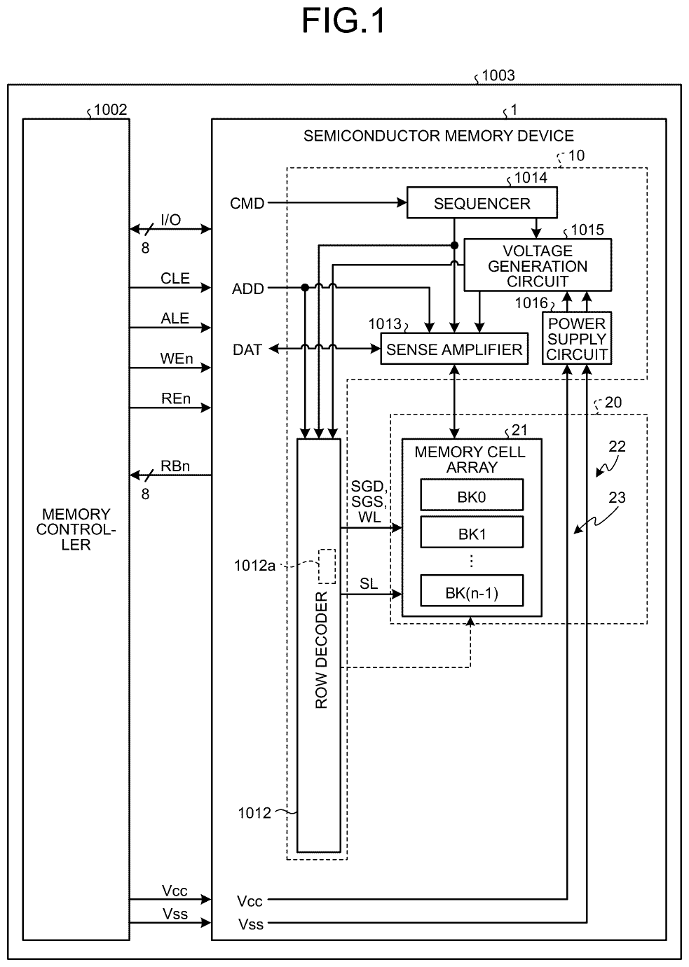

For example, a semiconductor memory device 1 can be configured as illustrated in FIG. 1. FIG. 1 is a block diagram illustrating the configuration of the semiconductor memory device 1.

The semiconductor memory device 1 includes a plurality of chips 10 and 20. The chip 20 includes a memory cell array 21 and is also referred to as an array chip. The chip 10 includes a peripheral circuit for controlling the memory cell array 21 and is also referred to as a circuit chip.

Although FIG. 1 illustrates a configuration in which the semiconductor memory device 1 includes two chips (array chips) 20, the semiconductor memory device 1 may include two or more array chips, or include two or more array chips stacked with each other.

The semiconductor memory device 1 may be nonvolatile memory that stores data as nonvolatile data, and is applicable to a memory system 1003 such as a memory card or a solid state drive (SSD). The memory system 1003 includes a semiconductor memory device 1 and a memory controller 1002.

The semiconductor memory device 1 receives, from the memory controller 1002, a power supply Vss, a power supply Vcc, a command latch enable signal CLE, an address latch enable signal ALE, a write enable signal WEn, a read enable signal REn, a ready/busy signal RBn, an input/output signal I/O, and the like. The semiconductor memory device 1 is controlled by the memory controller 1002 via these signals and the like.

The input/output signal I/O can include a command CMD, address information ADD, and a data signal DAT. The power supply Vss has a reference potential (for example, a ground potential). The power supply Vcc has a predetermined potential (for example, the power supply potential). The command latch enable signal CLE indicates that the input/output signal I/O is the command CMD. The address latch enable signal ALE indicates that the output signal I/O is the address information ADD. The write enable signal WEn can be used to enable a write operation. The read enable signal REn can be used to enable a read operation. The ready/busy signal RBn indicates that the semiconductor memory device 1 is in a ready/busy state.

The chip 20 includes power supply lines 22 and 23. The power supply Vss is transmitted to the chip 10 via the power supply line 22. The power supply Vcc is transmitted to the chip 10 via the power supply line 23.

The chip 10 further includes a memory cell array 21. The memory cell array 21 includes a plurality of memory cells three-dimensionally arranged in an array. Each memory cell array 21 includes a plurality of blocks BK.

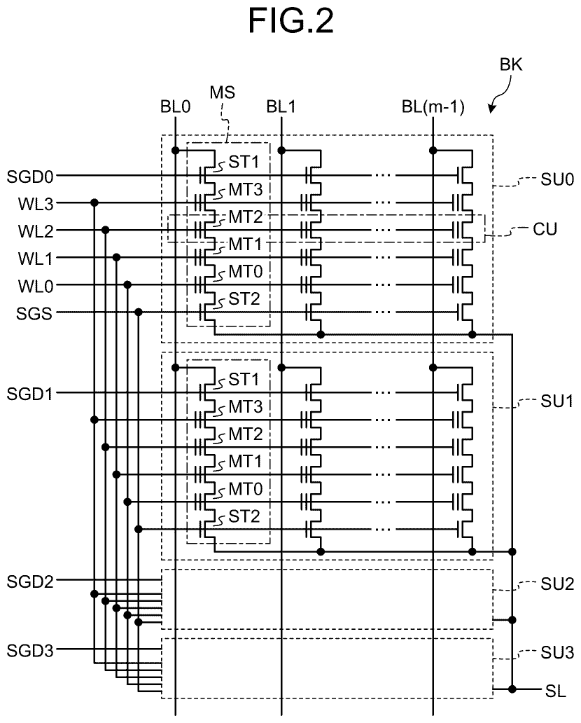

Each block BK corresponds to a set of a plurality of memory cell transistors to which the word line WL is commonly connected, and can be configured as illustrated in FIG. 2. FIG. 2 is a circuit diagram illustrating a configuration of the block BK.

The block BK includes four string units SU0 to SU3, for example. Each string unit SU includes a plurality of memory strings MS. The plurality of memory strings MS correspond to a plurality of bit lines BL0 to BL (m−1) (m is any integer of 2 or more). Each memory string MS is connected to the corresponding bit line BL. Each memory string MS includes memory cell transistors (hereinafter, referred to as memory cells) MT0 to MT3 and selection transistors ST1 and ST2.

In each memory string MS, the selection transistor ST1 has its drain connected to the bit line BL. Memory cell transistors MT0 to MT3 are connected in series between a source of the selection transistor ST1 and a drain of the selection transistor ST2. The selection transistor ST2 has its source connected to a source line SL.

The gate of the selection transistor ST1 of each memory string MS included in the string unit SU is commonly connected to the select gate line SGD. The gate of the selection transistor ST2 of each memory string MS included in the block BK is commonly connected to a select gate line SGS. The gates of the memory cell transistors MT of the memory strings MS included in the block BK are commonly connected to the word line WL.

In one string unit SU, a set of a plurality of memory cells MC connected to one word line WL is referred to as a cell unit CU. For example, when the memory cell MC stores p-bit data (p is an integer of 1 or more), the storage capacity of the cell unit CU is defined as p-page data.

Each bit line BL is connected to the drain of the selection transistor ST1 of the corresponding memory string MS of each string unit SU of the block BK. The source line SL is commonly connected to the source of the selection transistor ST2 of each memory string MS included in the block BK, and is shared among the string units SU of the block BK. The source line SL may be shared among the blocks BK.

The chip 10 (circuit chip) illustrated in FIG. 1 includes a row decoder 1012, a sense amplifier 1013, a sequencer 1014, a voltage generation circuit 1015, and a power supply circuit 1016.

The power supply circuit 1016 provides the power supplies Vss and Vcc received via the power supply lines 22 and 23 to individual portions. For example, the power supply circuit 1016 provides the power supplies Vss and Vcc to the voltage generation circuit 1015.

The sequencer 1014 integrally controls individual portions according to the command CMD. For example, the sequencer 1014 controls the write operation based on a write command CMD. In the control of the write operation, the sequencer 1014 writes the data DAT to the addressed memory cell MC in the memory cell array 21 and returns a write completion notification to the memory controller 1002. The sequencer 1014 controls the read operation in accordance with a read command CMD. In the control of the read operation, the sequencer 1014 reads the data DAT from the addressed memory cell MC in the memory cell array 21 and returns read data DAT to the memory controller 1002.

The voltage generation circuit 1015 generates a voltage according to the control of the sequencer 1014 using the power supplies Vss and Vcc, and supplies the generated voltage to the row decoder 1012 and the sense amplifier 1013.

The row decoder 1012 decodes the address information ADD, selects the word line WL corresponding to the selected memory cell as a written/read target in the memory cell array 21 based on the decoding result, and supplies a voltage to the selected word line WL. The row decoder 1012 selects select gate lines SGS and SGD corresponding to the selected memory cells according to the decoding result, and supplies a voltage to the select gate lines SGS and SGD that have been selected.

The row decoder 1012 includes a source driver 1012a. The row decoder 1012 selects a source line SL corresponding to the selected memory cell according to the decoding result, and controls the source driver 1012a to supply a voltage from the source driver 1012a to the source line SL.

The sense amplifier 1013 decodes the address information ADD, and selects the bit line BL corresponding to the memory cell as a write/read target in the memory cell array 21 according to the decoding result. The sense amplifier 1013 supplies a voltage to the selected bit line BL in the write processing. In read processing, the sense amplifier 1013 supplies the voltage of the selected bit line BL and senses the potential of the selected bit line BL.

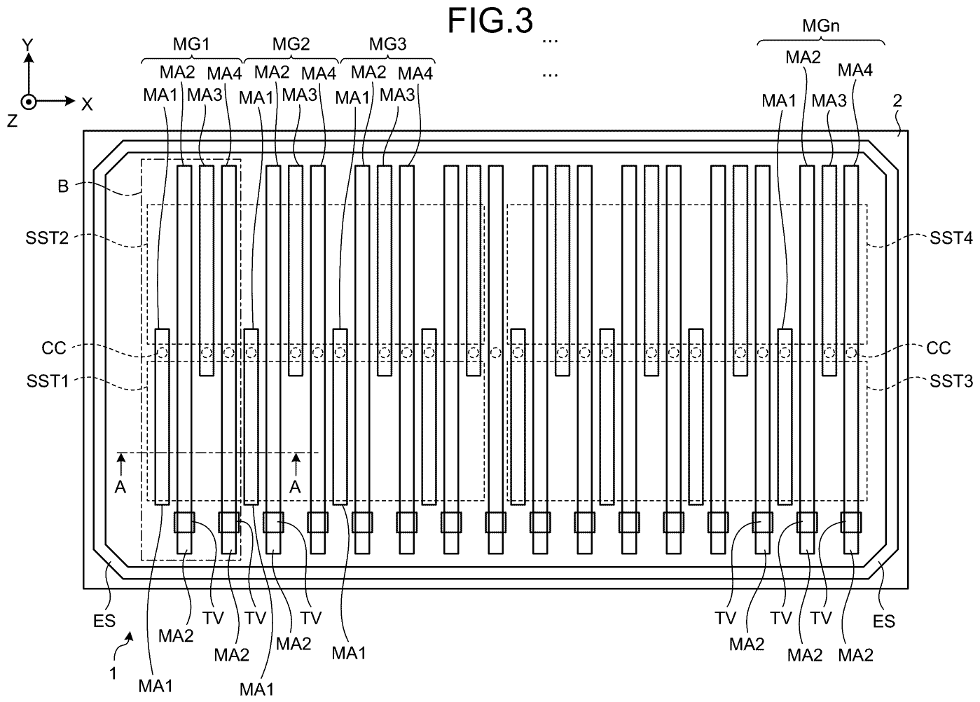

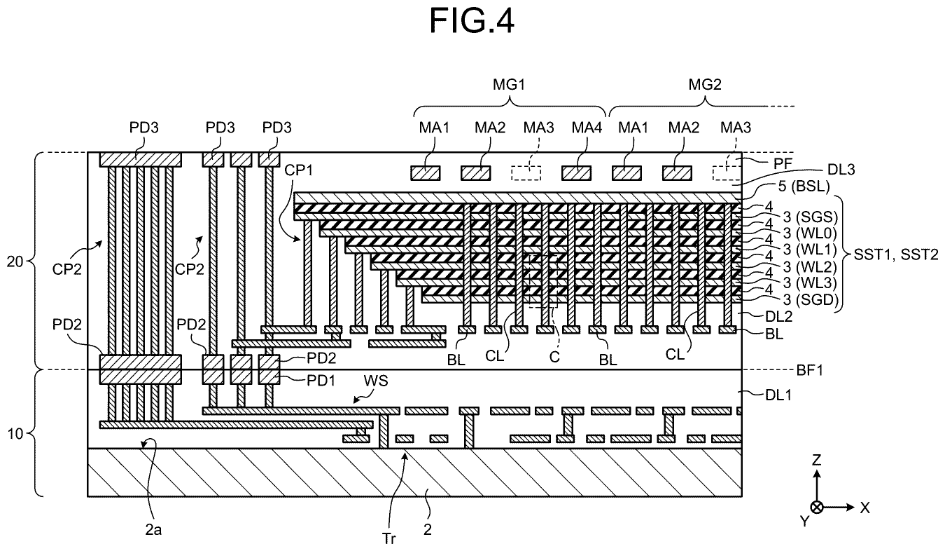

The power supply lines 22 and 23 and the source line SL illustrated in FIG. 1 can be implemented by a planar wiring line MA as illustrated in FIGS. 3 and 4, for example. Hereinafter, a direction perpendicular to the surface of the substrate 2 is referred to as a Z direction, and two directions orthogonal to each other in a plane perpendicular to the Z direction are referred to as an X direction and a Y direction. FIG. 3 is an XY-plane view illustrating a configuration of the semiconductor memory device 1. FIG. 4 is an XZ cross-sectional view illustrating a configuration of the semiconductor memory device 1. FIG. 4 illustrates a cross section of FIG. 3 taken along line A-A.

The semiconductor memory device 1 has a substantially rectangular shape in an XY-plane view, in which the X direction is set as a longitudinal direction, for example. The semiconductor memory device 1 can be formed with a stack of a plurality of chips, namely, the chips 10 and 20.

FIG. 3 illustrates a schematic layout configuration of each of the chips 10 and 20. The chip 20 includes a plurality of stacked bodies SST1 to SST4. The plurality of stacked bodies SST1 to SST4 may be two-dimensionally arranged in the XY direction. Each stacked body SST has a substantially rectangular shape in an XY-plane view, in which the X direction is set as a longitudinal direction, for example. Each stacked body SST functions as a part of the memory cell array 21.

There is provided a contact plug CC disposed between the stacked body SST1 and the stacked body SST2 (or between the stacked body SST3 and the stacked body SST4), which are disposed in the Y direction, among the plurality of stacked bodies SST1 to SST4. The contact plug CC extends in the Z direction between the stacked body SST1 and the stacked body SST2 (or between the stacked body SST3 and the stacked body SST4) and reaches the planar wiring line MA. The contact plug CC is electrically connected to a circuit element of the chip 10 via an electrode PD2 of the chip 20 and an electrode PD1 of the chip 10.

There is provided an edge seal ES as a structure shared by the chips 10 and 20. The edge seal ES surrounds the plurality of stacked bodies SST1 and SST2 from the outside in the XY direction when viewed as a see-through image in the Z direction. With this configuration, the edge seal ES provides an external electrostatic noise protection for the memory cell array 21 and control circuits therefor (including the row decoder 1012, the sense amplifier 1013, the sequencer 1014, the voltage generation circuit 1015, and the power supply circuit 1016).

Note that, for simplification, illustration of the configuration inside the edge seal ES in the chip 10 is omitted.

As illustrated in FIG. 4, the chip 20 is disposed on the +Z side of the chip 10. That is, the chip 20 is stacked on the +Z side of the chip 10. The chip 20 is a chip uses as a memory cell array chip, while the chip 10 is a chip used as a peripheral circuit chip.

The chip 10 is bonded to the main surface on the +Z side of the chip 20. The chip 20 may be bonded to the chip 10 by direct bonding. The chip 10 has, on its +Z side, an insulating film (for example, an oxide film) DL1 and an electrode PD1. The chip 20 has, on its +Z side, an insulating film (for example, an oxide film) DL1 and an electrode PD2. On a bonding surface BF1 of the chips 10 and 20, the insulating film DL1 of the chip 10 and the insulating film DL2 of the chip 20 are bonded to each other, and the electrode PD1 of the chip 10 and the electrode PD2 of the chip 20 are bonded to each other.

Note that a structure in which the chip 20 used as a memory cell array chip is bonded to the +Z side of the chip 10 used as a peripheral circuit chip is also referred to as a CMOS directly bonded to array (CBA) structure. In the CBA structure, the number of the chips 20 used as a memory cell array chip and bonded to the +Z side of the peripheral circuit chip 10, is not limited to one, and may be two or more.

The chip 10 includes a substrate 2, a transistor Tr, an electrode PD1, a wiring structure WS, and an insulating film DL1. The substrate 2 is disposed on the −Z side of the chip 10 and extends in a plate shape in the XY direction. The substrate 2 may be a semiconductor substrate, and can be formed of a material containing a semiconductor (for example, silicon) as a main component. The substrate 2 has a surface 2a, which is a +Z side surface. The transistor Tr functions as a circuit element of a circuit (including the row decoder 1012, the sense amplifier 1013, the sequencer 1014, the voltage generation circuit 1015, and the power supply circuit 1016) for controlling the memory cell array 21. The transistor Tr includes a gate electrode disposed as a conductive film on the surface 2a of the substrate 2, a source electrode/drain electrode disposed as a semiconductor region in the vicinity of the surface 2a within the substrate 2, and the like. As mentioned above, the electrode PD1 is disposed such that the surface thereof is exposed on the bonding surface BF1 of the chips 10 and 20. The wiring structure WS extends mainly in the Z direction so as to connect the gate electrode, the source electrode, the drain electrode, and the like of the transistor Tr to the electrode PD1.

The chip 20 includes a stacked body SST1, a conductive layer 5, a plurality of columnar bodies CL, a plurality of plugs CP1, a plurality of plugs CP2, a plurality of conductive films BL, a plurality of planar wiring lines MA, an electrode PD2, an electrode PD3, and an insulating film DL2. The stacked body SST1 includes a stack of a plurality of conductive layers 3 stacked in the Z direction, each of the conductive layers 3 stacked on each other via an insulating layer 4. The plurality of conductive layers 3 functions, in order from the −Z side to the +Z side, as the select gate line SGD, the word line WL3, the word line WL2, the word line WL1, the word line WL0, and the select gate line SGS. The conductive layer 5 functions as a cell source portion BSL. The cell source portion BSL is a part of the source line SL, and functions as an electrode in contact with the stacked body SST1 in the source line SL.

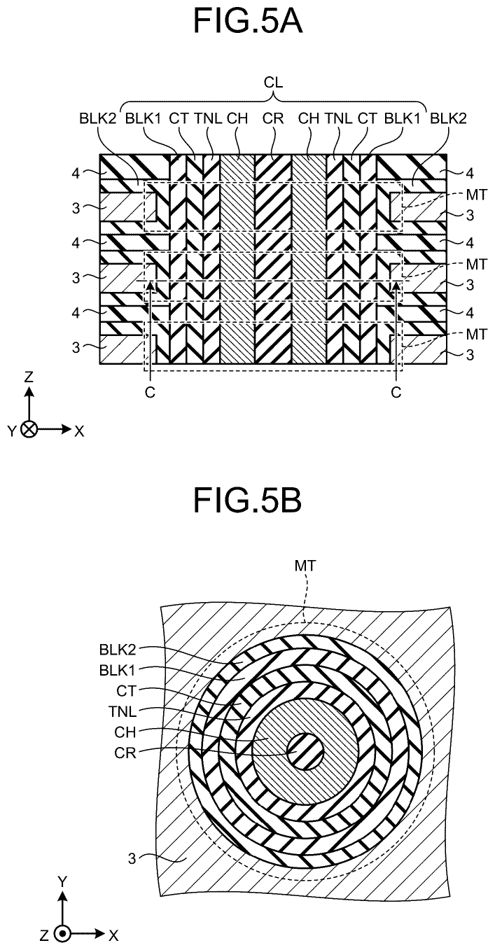

Each conductive layer 3 extends in a plate shape in the XY direction. Each columnar body CL extends in the Z direction through the plurality of conductive layers 3. Each columnar body CL may penetrate the stacked body SST1 in the Z direction. Each columnar body CL extends in a columnar manner in the Z direction. Each columnar body CL includes a semiconductor film CH (refer to FIGS. 5A and 5B) functioning as a channel region. The semiconductor film CH extends in a columnar manner (for example, in a columnar shape or a tubular shape) having an axis in the Z direction. The plurality of memory cells MC is formed at a plurality of intersecting positions where the plurality of conductive layers 3 and the plurality of columnar bodies CL intersect, that is, at a plurality of intersecting positions where the plurality of conductive layers 3 and the plurality of semiconductor films CH intersect.

As illustrated in FIGS. 5A and 5B, each columnar body CL includes an insulating film CR, a semiconductor film CH, an insulating film TNL, a charge storage film CT, and an insulating film BLK1. FIG. 5A is an XZ cross-sectional view illustrating the configuration of the memory cell MT, being an enlarged cross-sectional view of portion C in FIG. 4. FIG. 5B is an XY cross-sectional view illustrating the configuration of the memory cell MT, illustrating a cross section of FIG. 5A taken along line C-C. The insulating film CR extends in the Z direction and forms a columnar shape having an axis in the Z direction. The insulating film CR can be formed of an insulator such as silicon oxide. The semiconductor film CH extends in the Z direction so as to cover the insulating film CR from the outside in the XY direction, and has a tubular shape having an axis in the Z direction. The semiconductor film CH can be formed of a semiconductor such as polysilicon. The insulating film TNL extends in the Z direction so as to cover the semiconductor film CH from the outside in the XY direction, and has a tubular shape having an axis in the Z direction. The insulating film TNL can be formed of an insulator such as silicon oxide. The charge storage film CT extends in the Z direction so as to cover the insulating film TNL from the outside in the XY direction, and has a tubular shape having an axis in the Z direction. The charge storage film CT can be formed of an insulator such as silicon nitride. The insulating film BLK1 extends in the Z direction so as to cover the charge storage film CT from the outside in the XY direction, and has a tubular shape having an axis in the Z direction. The insulating film BLK1 can be formed of an insulator such as silicon oxide. The insulating film BLK2 covers the insulating film BLK1 from the outside in the XY direction, extends so as to cover surfaces on the conductive layer 3, specifically, a main surface on the +Z side, a main surface on the columnar body CL side, and a main surface on the −Z side, and forms a substantially hollow disc shape having an axis in the Z direction. The insulating film BLK2 can be formed of an insulator such as aluminum oxide. Portions surrounded by a dotted line in FIGS. 5A and 5B function as the memory cells MT.

As illustrated in FIG. 4, the tip of the semiconductor film CH in the columnar body CL reaches the conductive layer 5. The semiconductor film CH has its +Z side end connected to the conductive layer 5 while having its −Z side end connected to the conductive film BL via a plug. The conductive film BL functions as a bit line BL (refer to FIG. 2). The conductive layer 5 can be formed of a semiconductor (for example, polysilicon) to which conductivity is imparted. The conductive layer 5 functions as a cell source portion BSL in the source line SL (refer to FIG. 2). The semiconductor film CH functions as a channel region in the memory string MS (refer to FIG. 2).

The conductive layers 3 may have equal widths in the Y direction. The width of the plurality of conductive layers 3 in the X direction gradually increases from the −Z side to the +Z side. The conductive layers 3 provided in plurality are configured such that the X direction end is gradually positioned toward the outer side from the −Z side to the +Z side. This leads to formation of a staircase structure in which the select gate line SGD, the plurality of word lines WL, and the select gate line SGS are drawn out in a staircase shape in order from the −Z side to the +Z side at a plug connection portion in the memory cell array 11_1.

The plurality of plugs CP 1 correspond to the plurality of conductive layers 3. Each plug CP 1 is disposed between the electrode PD2 and the corresponding conductive layer 3 in the Z direction, specifically having its −Z side end electrically connected to the electrode PD2, extending in the Z direction, and having its +Z side end electrically connected to the corresponding conductive layer 3. This allows the plug CP 1 to electrically connect the electrode PD2 and the corresponding conductive layer 3 to each other.

The plurality of plugs CP 2 correspond to the plurality of electrodes PD2 and correspond to the plurality of electrodes PD3. Each plug CP 2 is disposed between the corresponding electrode PD2 and the corresponding electrode PD3 in the Z direction, specifically having its −Z side end electrically connected to the electrode PD2, extending in the Z direction, and having its +Z side end electrically connected to the corresponding electrode PD3. This allows the plug CP 2 to electrically connect the corresponding electrode PD2 and the corresponding electrode PD3.

The conductive films BL provided in plurality are disposed on the −Z side of the stacked body SST1. The conductive films BL provided in plurality are disposed in the X direction. Each of the conductive films BL extends in the Y direction. The plurality of conductive films BL correspond to the plurality of columnar bodies CL. Each conductive film BL is electrically connected to the −Z side end of the corresponding columnar body CL and functions as the bit line BL. The conductive film BL is electrically connected to the electrode PD2. This makes it possible for the bit line BL to be connected to the transistor Tr of the chip 10 via the electrode PD2, the electrode PD1, and the wiring structure WS.

The electrode PD2 is disposed to allow its surface to be exposed to the bonding surface BF1 of the chips 10 and 20. The electrode PD3 is disposed to allow its surface to be exposed to the bonding surface BF2 of the chip 20.

As illustrated in FIGS. 3 and 4, the plurality of planar wiring lines MA is arranged in the X direction. Each planar wiring line MA extends in the X direction and the Y direction, and has a substantially rectangular shape with the Y direction defined as a longitudinal direction in the XY-plane view. The plurality of planar wiring lines MA can be regularly arranged. A group of two or more planar wiring lines MA as a unit of arrangement will be referred to as a wiring line group MG.

The plurality of wiring line groups MG1 to MGn are arranged in the X direction, “n” is any integer of 2 or more. When viewed as a see-through image in the Z direction, each wiring line group MG overlaps a plurality of stacked bodies SST1 and SST2 (or SST3 and SST4) arranged in the Y direction.

Each wiring line group MG includes a plurality of planar wiring lines MA1 to MA4. The planar wiring lines MA are arranged in the X direction. When viewed as a see-through image in the Z direction, each planar wiring line MA overlaps a plurality of stacked bodies SST1 and SST2 (or SST3 and SST4) arranged in the Y direction. As illustrated in FIG. 4, the planar wiring lines MA1 to MA4 included in the wiring line group MG are disposed on the +Z side with respect to the stacked body SST1, the contact plug CC, and the stacked body SST2.

As illustrated in FIG. 4, each planar wiring line MA covers the stacked bodies SST1 and SST2 (or the stacked bodies SST3 and SST4) via an interlayer insulating film DL3 and the conductive layer 5. The conductive layer 5 covers the stacked bodies SST1 and SST2 from the +Z side. The interlayer insulating film DL3 covers the conductive layer 5 from the +Z side. The planar wiring lines MA1 to MA4 included in the wiring line group MG are disposed on the main surface on the +Z side of the interlayer insulating film DL3.

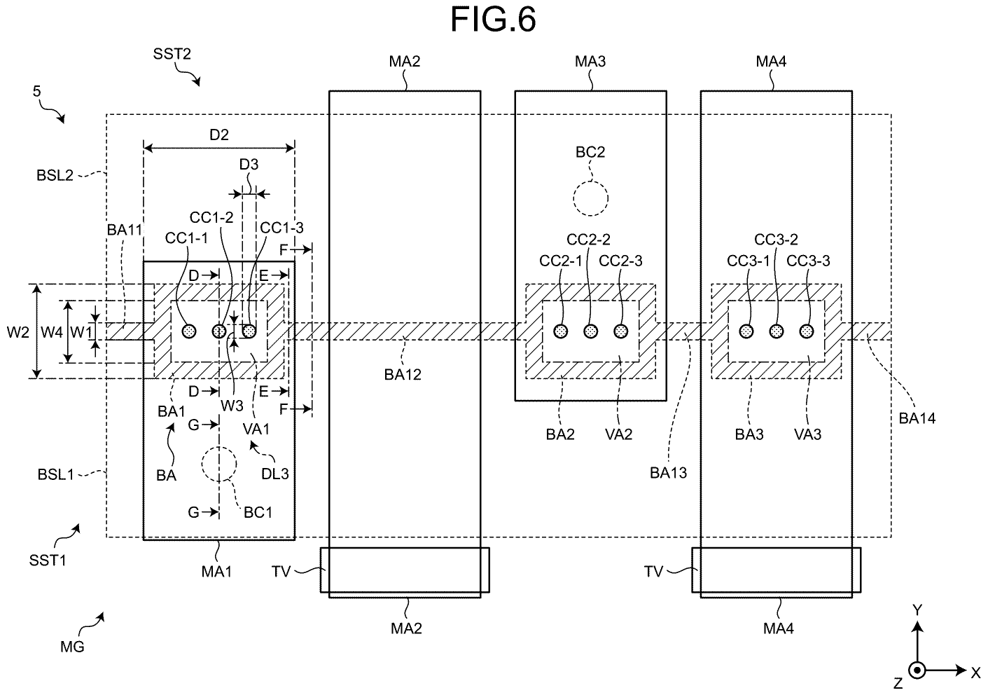

Next, a layout configuration regarding each of the planar wiring lines MA1 to MA4 included in the wiring line group MG will be described in more detail with reference to FIG. 6. FIG. 6 is a plan view illustrating a configuration of the semiconductor memory device 1. FIG. 6 illustrates an exemplary layout configuration related to the planar wiring lines MA1 to MA4. FIG. 6 is an enlarged plan view of portion B in FIG. 3. In FIG. 6, the enlargement ratio in the X direction is higher than the enlargement ratio in the Y direction with respect to FIG. 3.

FIG. 6 illustrates a layout configuration within the chip 20 located at the uppermost portion in the stacked structure of the plurality of chips 10 and 20. Each of the planar wiring lines MA1 to MA4 included in the wiring line group MG in the chip 20 is indicated by a thick solid line, the conductive layer 5 is indicated by a dotted line, and the interlayer insulating film DL3 is indicated by a one-dot chain line.

The conductive layer 5 includes a cell source portion BSL1, a cell source portion BSL2, and a division pattern BA. The interlayer insulating film DL3 has opening patterns VA1 to VA3.

The cell source portion BSL1 functions as a part of the source line SL for the stacked body SST1. The cell source portion BSL1 extends in the X direction and the Y direction, and has a substantially rectangular shape with the X direction as a longitudinal direction in the XY-plane view.

The cell source portion BSL2 functions as a part of the source line SL for the stacked body SST2. The cell source portion BSL2 is disposed on the +Y side with respect to the cell source portion BSL1. The cell source portion BSL2 extends in the X direction and the Y direction, and has a substantially rectangular shape with the X direction as a longitudinal direction in the XY-plane view.

The division pattern BA extends in the X direction between the cell source portion BSL1 and the cell source portion BSL2. When viewed as a see-through image in the Z direction, the pattern sequentially intersect the planar wiring lines MA1 to MA4 included in the wiring line group MG. The division pattern BA divides and electrically insulates the cell source portion BSL1 and the cell source portion BSL2 from each other. With this configuration, the division pattern BA electrically insulates the source line SL of the stacked body SST1 and the source line SL of the stacked body SST2 from each other.

Each planar wiring line MA extends in the X direction and the Y direction, and has a substantially rectangular shape with the Y direction as a longitudinal direction in the XY-plane view.

The division pattern BA extends in the arrangement direction of the plurality of planar wiring lines MA (that is, the X direction), and intersects with each of the plurality of planar wiring lines MA when viewed as a see-through image in the Z direction. When viewed as a see-through image in the Z direction, the division pattern BA internally includes the opening pattern VA at an XY position overlapping the planar wiring line MA and internally includes the contact plug CC at a position inside the opening pattern VA.

Regarding the division pattern BA, the maximum width, in the Y direction, of the portion not overlapping the planar wiring lines MA1 to MA4 is narrower than the maximum width, in the Y direction, of the portion overlapping the planar wiring lines MA1, 3, and 4 and corresponding to contact plugs CC1 to CC3.

The division pattern BA includes a groove pattern BA11, an opening pattern BA1, a groove pattern BA12, an opening pattern BA2, a groove pattern BA13, an opening pattern BA3, and a groove pattern BA14 in this order from the −X side to the +X side.

The groove pattern BA11 extends in a line shape in the X direction in the XY-plane view, and has its +X side end connected to the opening pattern BA1. The Y position of the groove pattern BA11 corresponds to the vicinity of the center of the opening pattern BA1 in the Y direction. When viewed as a see-through image in the Z direction, the groove pattern BA11 has its main portion not overlapping the planar wiring line MA1, but has its +X side end overlapping the planar wiring line MA1.

The opening pattern BA1 has a substantially rectangular shape in the XY-plane view. The opening pattern BA1 may have a substantially rectangular shape with the X direction defined as a longitudinal direction. The opening pattern BA1 overlaps the planar wiring line MA1 when viewed as a see-through image in the Z direction. The opening pattern BA1 internally includes the opening pattern VA1 and further internally includes the plurality of contact plugs CC1-1 to CC1-3 when viewed as a see-through image in the Z direction.

The opening pattern VA1 has a substantially rectangular shape in the XY-plane view. The opening pattern VA1 may have a substantially rectangular shape with the X direction defined as a longitudinal direction. The opening pattern VA1 overlaps the planar wiring line MA1 when viewed as a see-through image in the Z direction. The opening pattern VA1 internally includes a plurality of contact plugs CC1-1 to CC1-3 when viewed as a see-through image in the Z direction. The Y position of the groove pattern BA11 corresponds to the vicinity of the center of the opening pattern VA1 in the Y direction and corresponds to the Y position of the contact plug CC1.

The plurality of contact plugs CC1-1 to CC1-3 have a substantially circular shape or a substantially rectangular shape in the XY-plane view. The plurality of contact plugs CC1-1 to CC1-3 are arranged in the X direction. FIG. 6 illustrates a configuration in which each contact plug CC1 has a substantially circular shape in the XY-plane view, and the number of contact plugs CC1 included inside the opening pattern BA1 and the opening pattern VA1 when viewed as a see-through image in the Z direction is three. However, the number of contact plugs CC1 may be two or less, or four or more.

A Y-direction maximum width W1 of at least the main portion of the groove pattern BA11 is narrower than a Y-direction maximum width W2 of the opening pattern BA1. In addition, when viewed as a see-through image in the Z direction, the opening pattern VA1 is disposed at an XY position overlapping the opening pattern BA1 and is not disposed at an XY position overlapping the groove pattern BA11.

Here, when the interlayer insulating film DL3 and the planar wiring line MA are formed, the chip 20 located at the uppermost portion of the stacked structure of the plurality of chips 10 and 20 skips planarization so as to achieve process simplification. Therefore, when there is a large step at the corresponding XY position between the plurality of planar wiring lines MA on the main surface on the +Z side of the interlayer insulating film DL3, there is a possibility of occurrence of insufficient etching on the conductive film between the plurality of planar wiring lines MA at the time of forming the planar wiring lines MA, leading to defects of an occurrence of residual patterns.

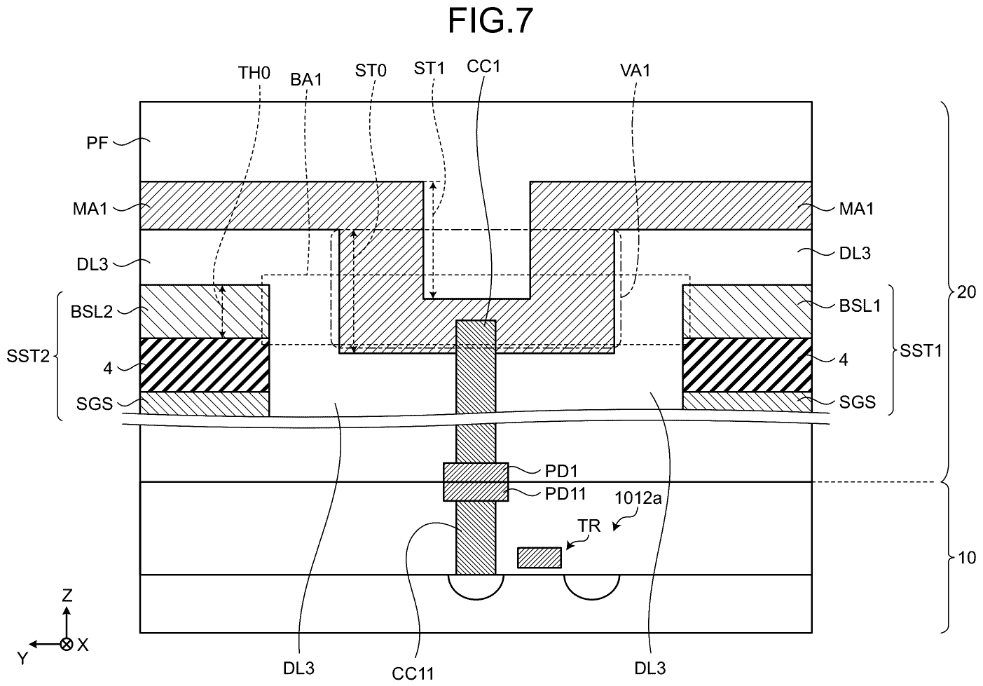

To handle this, using the layout configuration illustrated in FIG. 6, as illustrated in FIGS. 7 to 9, it is possible to suppress formation of a step on the main surface on the +Z side of the interlayer insulating film DL3 at the XY position between the planar wiring line MA1 and the planar wiring line MA2, leading to suppression of an occurrence of pattern defects such as a conductive film residue between the planar wiring line MA1 and the planar wiring line MA2 at the time of forming the planar wiring line MA.

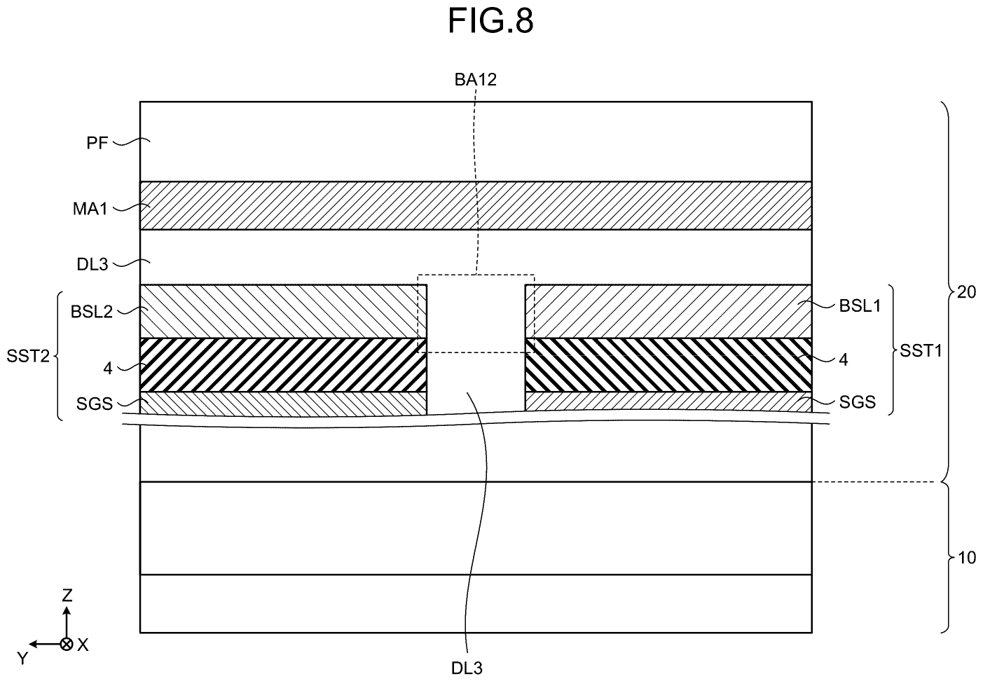

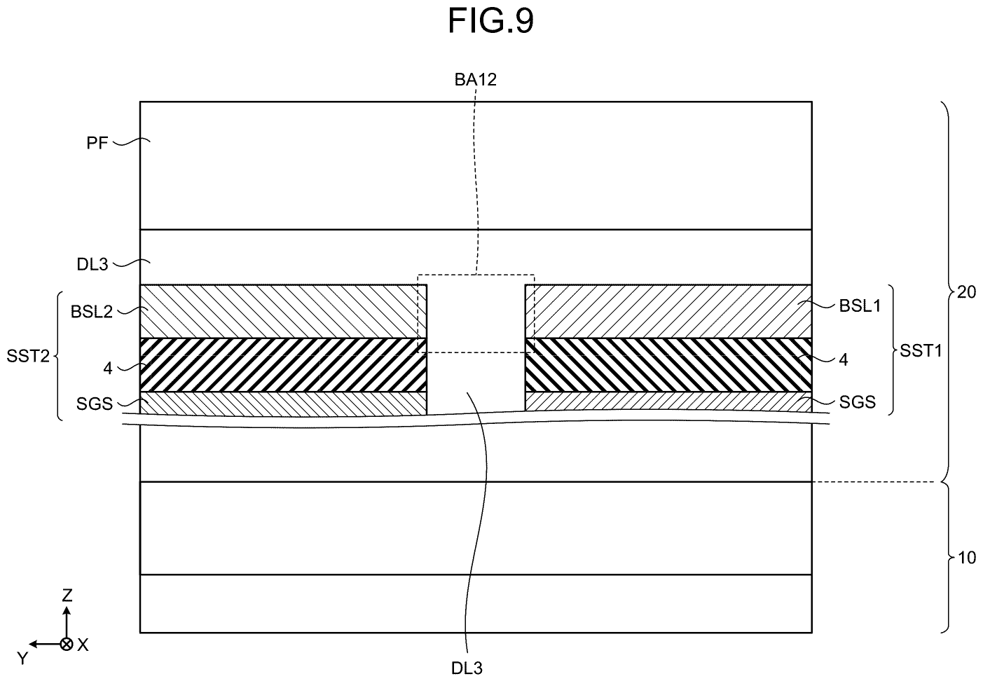

FIGS. 7 to 9 are YZ cross-sectional views each illustrating the configuration of the division pattern BA (the opening pattern BA1 and the groove pattern BA12). FIG. 7 illustrates a cross section of FIG. 6 taken along line D-D, indicating a YZ cross section of the opening pattern BA1 and the opening pattern VA1 at an XY position overlapping the planar wiring line MA1. FIG. 8 illustrates a cross section taken along line E-E in FIG. 6, including a YZ cross section of the groove pattern BA12 at an XY position overlapping the planar wiring line MA1. FIG. 9 illustrates a YZ cross section taken along line F-F in FIG. 6, including a YZ cross section of the groove pattern BA12 at an XY position not overlapping the planar wiring line MA1.

For example, the main surface on the +Z side of the interlayer insulating film DL3 at the XY position of the opening pattern BA has a relatively large step ST0 illustrated in FIG. 7. In contrast, the main surface on the +Z side of the interlayer insulating film DL3 at the XY position on the +X side of the opening pattern BA1 has almost no step or has a step less than a film thickness TH0 of the cell source portion BSL2 as illustrated in FIG. 8. The step ST0 corresponds to the Z depth of the opening pattern VA1 of the interlayer insulating film DL3. The size of the step ST0 is larger than the film thickness TH0 of the cell source portion BSL2. Further, as illustrated in FIG. 9, the main surface, on the +Z side, of the interlayer insulating film DL3 at the XY position on the +X side has almost no step or has a step less than the film thickness TH0 of the cell source portion BSL2.

Accordingly, the main surface on the +Z side of the planar wiring line MA1 at the XY position of the opening pattern BA1 has a relatively large step ST1 illustrated in FIG. 7. In contrast, the main surface on the +Z side of the planar wiring line MA1 at the XY position on the +X side of the opening pattern BA1 has almost no step or has a step less than the film thickness TH0 as illustrated in FIG. 8. The step ST1 corresponds to the step ST0. The step ST1 is larger than the film thickness TH0 of the cell source portion BSL2. Furthermore, as illustrated in FIG. 9, the conductive film corresponding to the planar wiring line MA1 is not disposed at the XY position on the +X side, and there is no remnant of the conductive film.

That is, with the layout configuration illustrated in FIG. 6, it is easy to suppress an occurrence of conductive film residue at the XY position between the planar wiring line MA1 and the planar wiring line MA2 at the time of forming the planar wiring line MA1, and it is possible to avoid occurrence of a short circuit between the planar wiring line MA1 and the planar wiring line MA2.

The Y-direction maximum width W1 of the +X side end of the groove pattern BA11 may be narrower than a Y-direction maximum width W4 of the opening pattern VA1. A Y-direction maximum width W3 of the contact plug CC1 may be narrower than the Y-direction maximum width W2 of the opening pattern BA1. The Y-direction maximum width W3 of the contact plug CC1 may be narrower than the Y-direction maximum width W4 of the opening pattern VA1. An X-direction maximum width D2 of the planar wiring line MA1 may be wider than an X-direction maximum width D3 of the contact plug CC1.

The groove pattern BA12 extends in a line shape in the X direction in the XY-plane view, and has its −X side end connected to the opening pattern BA1 and has its +X side end connected to the opening pattern BA2. The Y position of the groove pattern BA12 corresponds to the vicinity of the center of the opening pattern BA1 in the Y direction and corresponds to the vicinity of the center of the opening pattern BA2 in the Y direction. When viewed as a see-through image in the Z direction, the groove pattern BA12 has its main portion overlapping the planar wiring line MA2, has its-X side end overlapping the planar wiring line MA1, and has its +X side end overlapping the planar wiring line MA3. However, the groove pattern BA12 has its portion between the −X side end and the main portion not overlapping the planar wiring line MA, and has its portion between the main portion and the +X side end not overlapping the planar wiring line MA.

The opening pattern BA2 has a substantially rectangular shape in the XY-plane view. The opening pattern BA2 may have a substantially rectangular shape with the X direction defined as a longitudinal direction. The opening pattern BA2 overlaps the planar wiring line MA3 when viewed as a see-through image in the Z direction. The opening pattern BA2 internally includes the opening pattern VA2 and further internally includes a plurality of contact plugs CC2-1 to CC2-3 when viewed as a see-through image in the Z direction.

The opening pattern VA2 has a substantially rectangular shape in the XY-plane view. The opening pattern VA2 may have a substantially rectangular shape with the X direction defined as a longitudinal direction. The opening pattern VA2 overlaps the planar wiring line MA3 when viewed as a see-through image in the Z direction. The opening pattern VA2 internally includes a plurality of contact plugs CC2-1 to CC2-3 when viewed as a see-through image in the Z direction. The Y position of the groove pattern BA12 corresponds to the vicinity of the center of the opening patterns VA1 and VA2 in the Y direction and corresponds to the Y position of the contact plugs CC1 and CC2.

The plurality of contact plugs CC2-1 to CC2-3 have a substantially circular shape or a substantially rectangular shape in the XY-plane view. The plurality of contact plugs CC2-1 to CC2-3 are arranged in the X direction. FIG. 6 illustrates a configuration in which the number of contact plugs CC1 included inside the opening pattern BA2 and the opening pattern VA2 when viewed as a see-through image in the Z direction is three. However, the number of contact plugs CC2 may be two or less, or four or more.

The Y-direction maximum width of a portion at least between the −X side end and the main portion in the groove pattern BA12 is narrower than the Y-direction maximum width of each of the opening patterns BA1 and BA2. The Y-direction maximum width of a portion at least between the main portion and +X side end in the groove pattern BA12 is narrower than the Y-direction maximum width of each of the opening patterns BA1 and BA2. In addition, when viewed as a see-through image in the Z direction, the opening patterns VA1 and VA2 are each disposed at an XY position overlapping the opening patterns BA1 and BA2 respectively and are not disposed at an XY position overlapping the groove pattern BA12.

With this layout configuration, it is possible to suppress formation of a step on the main surface on the +Z side of the interlayer insulating film DL3 at the XY position between the planar wiring line MA1 and the planar wiring line MA2 or at the XY position between the planar wiring line MA2 and the planar wiring line MA3, and it is possible to suppress an occurrence of a pattern defect such as a conductive film residue between the planar wiring line MA1 and the planar wiring line MA2 or between the planar wiring line MA2 and the planar wiring line MA3 (refer to FIGS. 7 to 9).

The Y-direction maximum width of the +X side end of the groove pattern BA12 may be narrower than a Y-direction maximum width of the opening pattern VA2. A Y-direction maximum width of the contact plug CC2 may be narrower than the Y-direction maximum width of the opening pattern BA1. A Y-direction maximum width of the contact plug CC1 may be narrower than the Y-direction maximum width of the opening pattern VA1. An X-direction maximum width of the planar wiring line MA1 may be wider than an X-direction maximum width of the contact plug CC1.

The groove pattern BA13 extends in a line shape in the X direction in the XY-plane view, and has its −X side end connected to the opening pattern BA2 and its +X side end connected to the opening pattern BA3. The Y position of the groove pattern BA12 corresponds to the vicinity of the center of the opening pattern BA2 in the Y direction and corresponds to the vicinity of the center of the opening pattern BA3 in the Y direction. When viewed as a see-through image in the Z direction, the groove pattern BA13 has its main portion not overlapping the planar wiring lines MA3 or MA4, but has its −X side end overlapping the planar wiring line MA3 and its +X side end overlapping the planar wiring line MA4.

The opening pattern BA3 has a substantially rectangular shape in the XY-plane view. The opening pattern BA3 may have a substantially rectangular shape with the X direction defined as a longitudinal direction. The opening pattern BA3 overlaps the planar wiring line MA4 when viewed as a see-through image in the Z direction. The opening pattern BA3 internally includes the opening pattern VA3 and further internally includes the plurality of contact plugs CC3-1 to CC3-3 when viewed as a see-through image in the Z direction.

The opening pattern VA3 has a substantially rectangular shape in the XY-plane view. The opening pattern VA3 may have a substantially rectangular shape with the X direction defined as a longitudinal direction. The opening pattern VA3 overlaps the planar wiring line MA1 when viewed as a see-through image in the Z direction. The opening pattern VA3 internally includes a plurality of contact plugs CC3-1 to CC3-3 when viewed as a see-through image in the Z direction. The Y position of the groove pattern BA13 corresponds to the vicinity of the center of the opening patterns VA2 and VA3 in the Y direction and corresponds to the Y position of the contact plugs CC2 and CC3.

The plurality of contact plugs CC3-1 to CC3-3 have a substantially circular shape or a substantially rectangular shape in the XY-plane view. The plurality of contact plugs CC3-1 to CC3-3 are arranged in the X direction. FIG. 6 illustrates a configuration in which each contact plug CC3 has a substantially circular shape in the XY-plane view, and the number of contact plugs CC3 included inside the opening pattern BA3 and the opening pattern VA3 when viewed as a see-through image in the Z direction is three. However, the number of contact plugs CC3 may be two or less, or four or more.

The groove pattern BA14 extends in a line shape in the X direction in the XY-plane view, and the −X side end is connected to the opening pattern BA3. The Y position of the groove pattern BA14 corresponds to the vicinity of the center of the opening pattern BA3 in the Y direction and corresponds to the vicinity of the center of the opening pattern BA1 in the Y direction. When viewed as a see-through image in the Z direction, the groove pattern BA14 has its −X side end overlapping the planar wiring line MA4, with no overlapping of its main portion with the planar wiring line MA4. The Y position of the groove pattern BA14 corresponds to the vicinity of the center of the opening pattern VA3 in the Y direction and corresponds to the Y position of the contact plug CC3.

The Y-direction maximum width of at least the main portion in the groove pattern BA13 is narrower than the Y-direction maximum width of each of the opening patterns BA2 and BA3. In addition, when viewed as a see-through image in the Z direction, the opening patterns VA2 and VA3 are each disposed at an XY position overlapping the opening patterns BA2 and BA3 respectively and is not disposed at an XY position overlapping the groove pattern BA13.

With this layout configuration, it is possible to suppress formation of a step on the main surface on the +Z side of the interlayer insulating film DL3 at the XY position between the planar wiring line MA3 and the planar wiring line MA4, leading to suppression of an occurrence of pattern defects such as a conductive film residue between the planar wiring line MA3 and the planar wiring line MA4 (refer to FIGS. 7 to 9).

The Y-direction maximum width of the +X side end of the groove pattern BA13 may be narrower than a Y-direction maximum width of the opening patterns VA2 and VA3. A Y-direction maximum width of the contact plugs CC2 and CC3 may be narrower than the Y-direction maximum width of the opening patterns BA2 and BA3. A Y-direction maximum width of the contact plugs CC2 and CC3 may be narrower than the Y-direction maximum width of the opening patterns VA2 and VA3. An X-direction maximum width of the planar wiring line MA3 and MA4 may be wider than the X-direction maximum width of the contact plugs CC2 and CC3.

A Y-direction maximum width of at least the main portion of the groove pattern BA14 is narrower than a Y-direction maximum width of the opening pattern BA3. Furthermore, the Y-direction maximum width of the −X side end of the groove pattern BA14 may be narrower than a Y-direction maximum width of the opening pattern BA3.

With this layout configuration, it is possible to suppress formation of a step on the main surface on the +Z side of the interlayer insulating film DL3 at the XY position (refer to FIG. 3) between the planar wiring line MA4 and the planar wiring line MA1, leading to suppression of the occurrence of pattern defects such as a conductive film residue between the planar wiring line MA4 and the planar wiring line MA1 (refer to FIGS. 7 to 9).

The Y-direction maximum width of the main portion of the groove pattern BA14 may be narrower than a Y-direction maximum width of the opening pattern VA3.

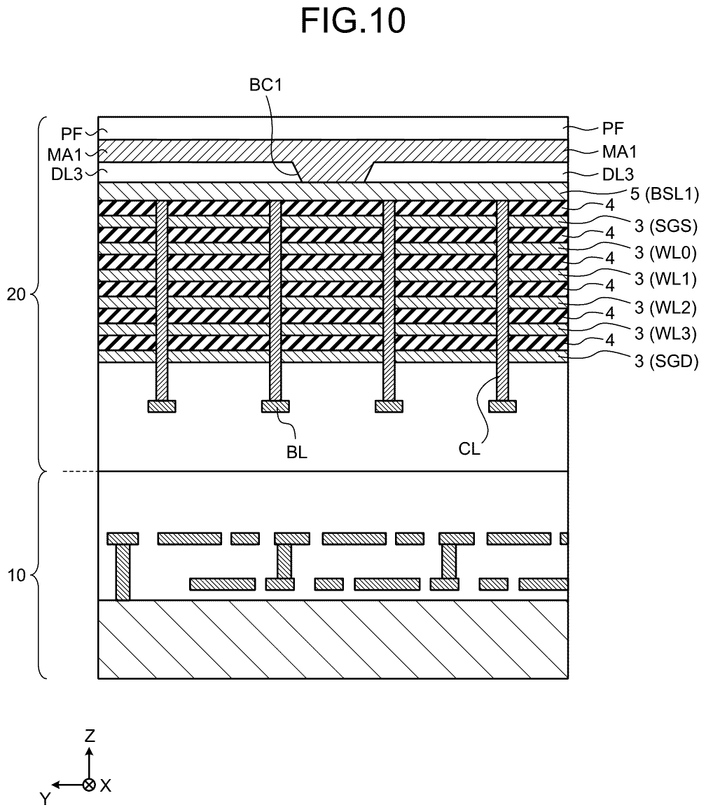

In addition, the planar wiring line MA1 may function as a part of the source line SL for the stacked body SST1 as illustrated in FIGS. 6, 7, and 10. FIG. 10 is a YZ cross-sectional view illustrating the configuration of the connection portion of the planar wiring line MA1 to the cell source portion BSL. FIG. 10 illustrates a cross section of FIG. 6 taken along line G-G.

The electrode PD1 of the chip 20 and the electrode PD11 of the chip 10 illustrated in FIG. 7 are directly bonded to each other at a bonding surface. In the XY position between the cell source portion BSL1 and the cell source portion BSL2 in the chip 20, the planar wiring line MA1 is electrically connected to the contact plug CC1, and the contact plug CC1 is electrically connected to the electrode PD1. The electrode PD1 is electrically connected to the electrode PD11 at the bonding surface. In the chip 10, the electrode PD11 is electrically connected to a circuit element TR of the source driver 1012a via the contact plug CC11. The planar wiring line MAI illustrated in FIG. 10 is connected to the cell source portion BSL1 via a conductive plug BC 1.

With this configuration, the voltage generated in the source driver 1012a can be supplied to the cell source portion BSL1 via the contact plug CC11, the electrode PD11, the electrode PD1, the contact plug CC1, the planar wiring line MA1, and the conductive plug BC 1 (refer to FIG. 6). At this time, the contact plug CC11, the electrode PD11, the electrode PD1, the contact plug CC1, the planar wiring line MA1, the conductive plug BC 1, and the cell source portion BSL1 function as the source line SL (refer to FIGS. 1 and 2). The planar wiring line MA1 functions as a part of the source line SL.

Similarly, the planar wiring line MA3 may function as a part of the source line SL for the stacked body SST2 as illustrated in FIG. 6. The planar wiring line MA3 may be connected to the cell source portion BSL2 via the conductive plug BC 2.

As described above, in the first embodiment, the semiconductor memory device 1 has a configuration in which the division pattern BA dividing the cell source portion BSL1 of the stacked body SST1 and the cell source portion BSL2 of the stacked body SST2 extends in the arrangement direction of the plurality of planar wiring lines MA, and intersects each of the plurality of planar wiring lines MA when viewed as a see-through image in the Z direction. Regarding the division pattern BA, the maximum width, in the Y direction, of the portion not overlapping the planar wiring lines MA1 to MA4 is narrower than the maximum width, in the Y direction, of the portion overlapping the planar wiring lines MA1, MA3, and MA4 and corresponding to the contact plug CC. With this configuration, it is possible to suppress formation of a step on the main surface on the +Z side of the interlayer insulating film DL3 at the XY position between the plurality of planar wiring lines MA, leading to achievement of a layout configuration capable of suppressing occurrence of a pattern defect such as a conductive film residue between the plurality of planar wiring lines MA at the time of forming the planar wiring line MA. That is, it is possible to optimize the layout configuration in the chip 20 located at the uppermost portion in the structure in which the plurality of chips 10 and 20 are stacked.

### Second Embodiment

Next, a semiconductor memory device 101 according to a second embodiment will be described. In the following, portions different from the first embodiment will be mainly described.

The first embodiment has exemplified a layout configuration in which the Y positions of the groove patterns BA11 to BA14 in the division pattern BA are in the vicinity of the centers of the opening patterns BA1 to BA3 in the Y direction. In contrast, the second embodiment will exemplify a layout configuration in which the Y positions of the groove patterns BA11 to BA14 in the division pattern BA are shifted from the vicinity of the centers of the opening patterns BA1 to BA3 in the Y direction.

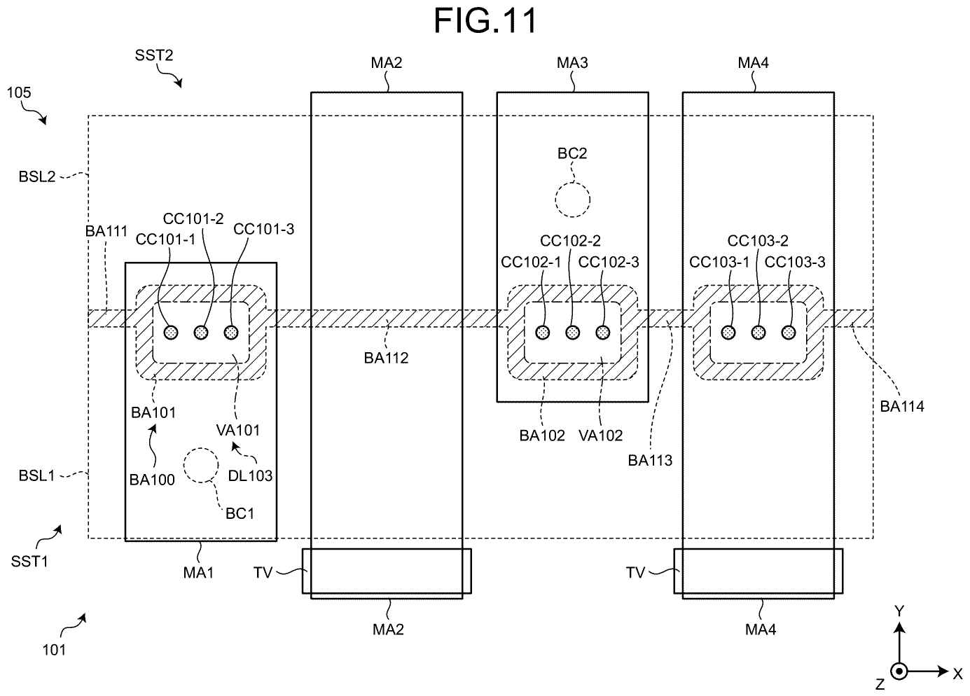

The layout related to each of the planar wiring lines MA1 to MA4 included in the wiring line group MG may have a configuration as illustrated in FIG. 11. FIG. 11 is a plan view illustrating the configuration of the semiconductor memory device 101 according to the second embodiment. FIG. 11 illustrates a layout configuration related to the planar wiring lines MA1 to MA4 corresponding to FIG. 6.

FIG. 11 illustrates a layout configuration within the chip 20 located at the uppermost portion in the stacked structure of the plurality of chips 10 and 20. Each of the planar wiring lines MA1 to MA4 included in the wiring line group MG in the chip 20 is indicated by a thick solid line, a conductive layer 105 is indicated by a dotted line, and an interlayer insulating film DL103 is indicated by a one-dot chain line.

The conductive layer 105 includes a division pattern BA100 instead of the division pattern BA (refer to FIG. 6). The interlayer insulating film DL103 includes opening patterns VA101 to VA103 instead of the opening patterns VA1 to VA3, respectively (refer to FIG. 6).

The division pattern BA100 includes a groove pattern BA111, an opening pattern BA101, a groove pattern BA112, an opening pattern BA102, a groove pattern BA113, an opening pattern BA103, and a groove pattern BA114 in this order from the −X side to the +X side.

The Y position of the groove pattern BA111 is shifted from the vicinity of the center of the opening pattern BA101 in the Y direction to the +Y side, shifted from the vicinity of the center of the opening pattern VA101 in the Y direction to the +Y side, and is shifted from the Y position of the contact plug CC101 to the +Y side.

The Y position of the groove pattern BA112 is shifted from the vicinity of the center in the Y direction of the opening patterns BA101 and BA102 to the +Y side, shifted from the vicinity of the center in the Y direction of the opening patterns VA101 and VA102 to the +Y side, and is shifted from the Y position of the contact plugs CC101 and CC102 to the +Y side.

The Y position of the groove pattern BA113 is shifted from the vicinity of the center in the Y direction of the opening patterns BA102 and BA103 to the +Y side, shifted from the vicinity of the center in the Y direction of the opening patterns VA102 and VA103 to the +Y side, and is shifted from the Y position of the contact plugs CC102 and CC103 to the +Y side.

The Y position of the groove pattern BA114 is shifted from the vicinity of the center of the opening pattern BA103 in the Y direction to the +Y side, shifted from the vicinity of the center of the opening pattern VA103 in the Y direction to the +Y side, and is shifted from the Y position of the contact plug CC103 to the +Y side.

The division pattern BA100 is similar to the case of the first embodiment in that the maximum width, in the Y direction, of the portion not overlapping the planar wiring lines MA1 to MA4 is narrower than the maximum width, in the Y direction, of the portion overlapping the planar wiring lines MA1, MA3, and MA4 and corresponding to the contact plug CC.

As described above, in the second embodiment, the semiconductor memory device 101 has a configuration in which the maximum width, in the Y direction, of the portion not overlapping the planar wiring lines MA1 to MA4 of the division pattern BA100 is narrower than the maximum width, in the Y direction, of the portion overlapping the planar wiring lines MA1, MA3, and MA4 and corresponding to the contact plug CC. With this configuration, it is possible to suppress formation of a step on the main surface on the +Z side of the interlayer insulating film DL3 at the XY position between the plurality of planar wiring lines MA, leading to achievement of a layout configuration capable of suppressing occurrence of a pattern defect such as a conductive film residue between the plurality of planar wiring lines MA at the time of forming the planar wiring line MA. That is, it is possible to optimize the layout configuration in the chip 20 located at the uppermost portion in the structure in which the plurality of chips 10 and 20 are stacked.

The Y position of each of the groove patterns BA111 to BA114 may be shifted from the vicinity of the center in the Y direction of the opening patterns BA101 to BA103 to the −Y side.

### Third Embodiment

Next, a semiconductor memory device 201 according to a third embodiment will be described. In the following, portions different from the first embodiment and the second embodiment will be mainly described.

The first embodiment and the second embodiment have exemplified a layout configuration of a division pattern in which the groove pattern and the opening pattern are repeated in the X direction. In contrast, the third embodiment will exemplify a layout configuration of a division pattern in which the groove pattern extends in the X direction at a position separated from the opening pattern in the Y direction.

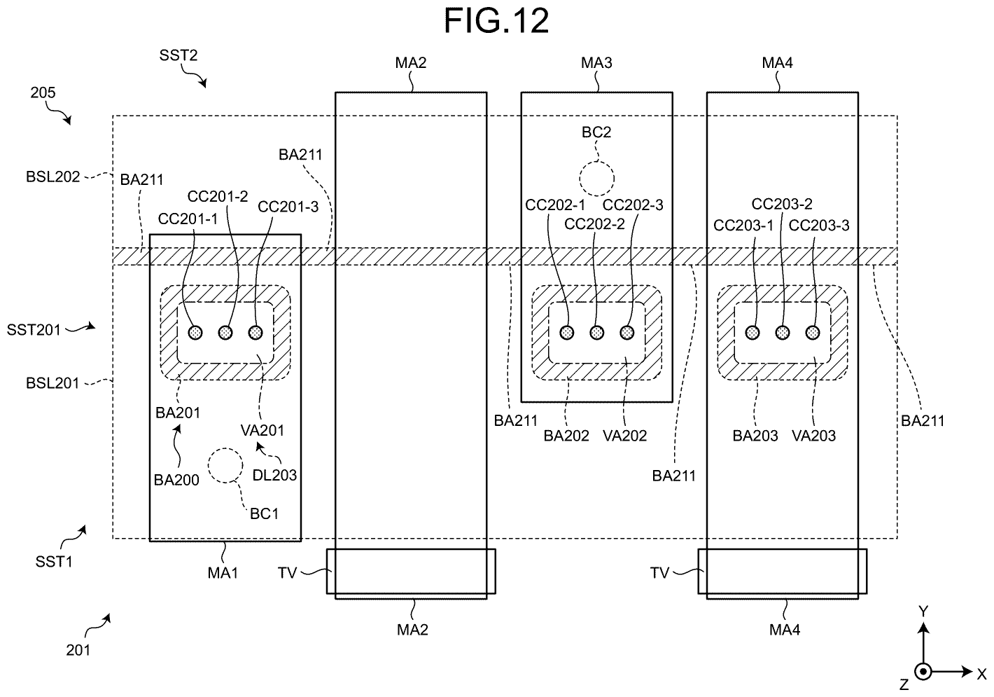

The layout related to each of the planar wiring lines MA1 to MA4 included in the wiring line group MG may have a configuration as illustrated in FIG. 12. FIG. 12 is a plan view illustrating the configuration of the semiconductor memory device 201 according to the third embodiment. FIG. 12 illustrates a layout configuration related to the planar wiring lines MA1 to MA4 corresponding to FIG. 6.

FIG. 12 illustrates a layout configuration within the chip 20 located at the uppermost portion in the stacked structure of the plurality of chips 10 and 20. Each of the planar wiring lines MA1 to MA4 included in the wiring line group MG in the chip 20 is indicated by a thick solid line, a conductive layer 205 is indicated by a dotted line, and an interlayer insulating film DL203 is indicated by a one-dot chain line.

The conductive layer 205 includes a cell source portion BSL201, a cell source portion BSL202, and a division pattern BA200 instead of the cell source portion BSL1, the cell source portion BSL2, and the division pattern BA, respectively (refer to FIG. 6). The interlayer insulating film DL203 includes opening patterns VA201 to VA203 instead of the opening patterns VA1 to VA3, respectively (refer to FIG. 6).

The division pattern BA200 has its part extending in the X direction between the cell source portion BSL201 and the cell source portion BSL202, and has its another part disposed at a position inside the cell source portion BSL201 or the cell source portion BSL202 when viewed as a see-through image in the Z direction.

The division pattern BA200 includes a groove pattern BA211, an opening pattern BA201, an opening pattern BA202, and an opening pattern BA203.

The groove pattern BA211 extends in the X direction between the cell source portion BSL201 and the cell source portion BSL202. The groove pattern BA211 is disposed to be separated, on the +Y side, from each of the opening pattern BA201, the opening pattern BA202, and the opening pattern BA203.

The opening pattern BA201, the opening pattern BA202, and the opening pattern BA203 are disposed at positions inside the cell source portion BSL201 when viewed as a see-through image in the Z direction. The opening pattern BA201, the opening pattern BA202, and the opening pattern BA203 are arranged in order from the −X side to the +X side. The opening pattern BA201, the opening pattern BA202, and the opening pattern BA203 are separated from each other in the X direction.

Here, the maximum width of the groove pattern BA211 in the Y direction is narrower than the maximum widths of the opening patterns BA201, BA202, and BA203 in the Y direction. The maximum width of the groove pattern BA211 in the Y direction corresponds to the maximum width, in the Y direction, of a portion not overlapping the planar wiring lines MA1 to MA4 in the division pattern BA200. The maximum widths of the opening patterns BA201, BA202, and BA203 in the Y direction correspond to the maximum widths, in the Y direction, of the portions overlapping the planar wiring lines MA1, MA3, and MA4 and corresponding to the contact plugs CC. That is, in the division pattern BA200, the maximum width, in the Y direction, of the portion not overlapping the planar wiring line MA is narrower than the maximum width, in the Y direction, of the portion overlapping the planar wiring line MA and corresponding to the contact plug CC.

As described above, in the third embodiment, the semiconductor memory device 201 has a configuration in which the maximum width, in the Y direction, of the portion not overlapping the planar wiring lines MA1 to MA4 of the division pattern BA200 is narrower than the maximum width, in the Y direction, of the portion overlapping the planar wiring lines MA1, MA3, and MA4 and corresponding to the contact plug CC. With this configuration, it is possible to suppress formation of a step on the main surface on the +Z side of the interlayer insulating film DL203 at the XY position between the plurality of planar wiring lines MA, leading to achievement of a layout configuration capable of suppressing occurrence of a pattern defect such as a conductive film residue between the plurality of planar wiring lines MA at the time of forming the planar wiring line MA. That is, it is possible to optimize the layout configuration in the chip 20 located at the uppermost portion in the structure in which the plurality of chips 10 and 20 are stacked.

Note that the groove pattern BA211 may be disposed to be separated, on the −Y side, from each of the opening pattern BA201, the opening pattern BA202, and the opening pattern BA203. In this case, the opening pattern BA201, the opening pattern BA202, and the opening pattern BA203 may be disposed at positions inside the cell source portion BSL202 when viewed as a see −through image in the Z direction.

### Fourth Embodiment

Next, a semiconductor memory device 301 according to a fourth embodiment will be described. In the following, portions different from the first embodiment to the third embodiment will be mainly described.

The third embodiment has exemplified a layout configuration of a division pattern in which the groove pattern extends in the X direction at a position separated from the opening pattern in the Y direction. In contrast, the fourth embodiment will exemplify a layout configuration of a division pattern in which two groove patterns extend in the X direction at positions separated from both sides of the opening pattern in the Y direction.

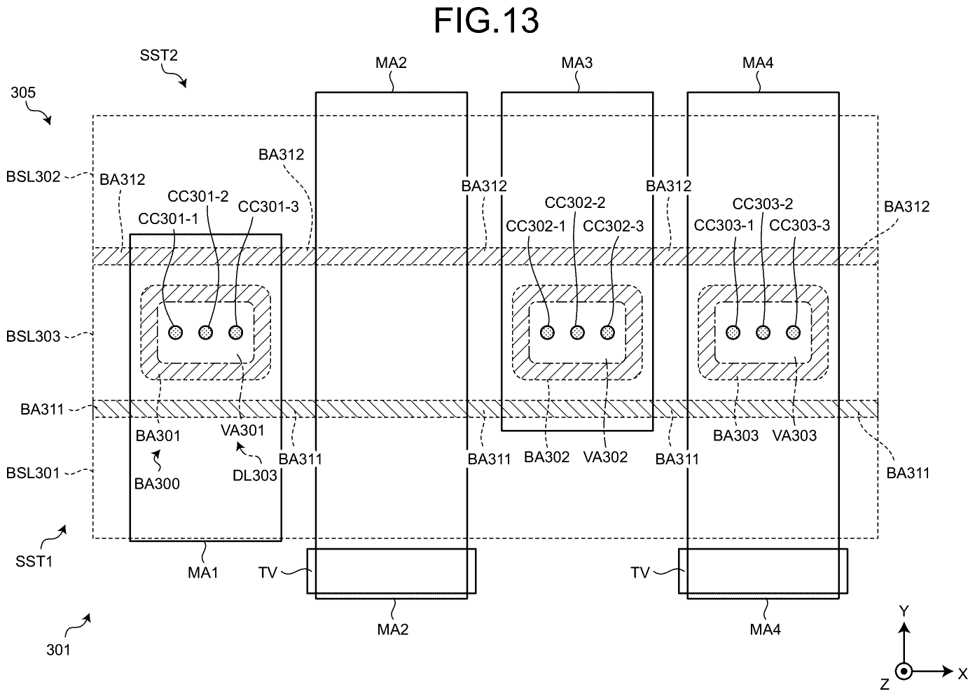

The layout related to each of the planar wiring lines MA1 to MA4 included in the wiring line group MG may have a configuration as illustrated in FIG. 13. FIG. 13 is a plan view illustrating the configuration of the semiconductor memory device 301 according to the fourth embodiment. FIG. 13 illustrates a layout configuration related to the planar wiring lines MA1 to MA4 corresponding to FIG. 6.

FIG. 13 illustrates a layout configuration within the chip 20 located at the uppermost portion in the stacked structure of the plurality of chips 10 and 20. Each of the planar wiring lines MA1 to MA4 included in the wiring line group MG in the chip 20 is indicated by a thick solid line, a conductive layer 305 is indicated by a dotted line, and an interlayer insulating film DL303 is indicated by a one-dot chain line.

The conductive layer 305 includes a cell source portion BSL301, a cell source portion BSL302, a dummy cell source portion BSL303, and a division pattern BA300 instead of the cell source portion BSL201, the cell source portion BSL202, and the division pattern BA200, respectively (refer to FIG. 12). The interlayer insulating film DL303 includes opening patterns VA301 to VA303 instead of the opening patterns VA201 to VA203, respectively (refer to FIG. 12).

The dummy cell source portion BSL303 is a cell source portion being a dummy portion and does not function as a part of the source line SL. The dummy cell source portion BSL303 is disposed between the cell source portion BSL301 and the cell source portion BSL302 in the Y direction. The dummy cell source portion BSL303 extends in the X direction and the Y direction, and has a substantially rectangular shape with the X direction as a longitudinal direction in the XY-plane view.

The division pattern BA300 has one part extending in the X direction between the cell source portion BSL301 and the dummy cell source portion BSL303, another part extending in the X direction between the dummy cell source portion BSL303 and the cell source portion BSL302, and still another part being disposed at a position inside the dummy cell source portion BSL303 when viewed as a see-through image in the Z direction.

The division pattern BA300 includes a groove pattern BA311, a groove pattern BA312, an opening pattern BA301, an opening pattern BA302, and an opening pattern BA303.

The groove pattern BA311 extends in the X direction between the cell source portion BSL301 and the dummy cell source portion BSL303. The groove pattern BA311 is disposed to be separated, on the-Y side, from each of the opening pattern BA301, the opening pattern BA302, and the opening pattern BA303.

The groove pattern BA312 extends in the X direction between the dummy cell source portion BSL303 and the cell source portion BSL302. The groove pattern BA312 is disposed to be separated, on the +Y side, from each of the opening pattern BA301, the opening pattern BA302, and the opening pattern BA303.

The opening pattern BA301, the opening pattern BA302, and the opening pattern BA303 are disposed at positions inside the dummy cell source portion BSL303 when viewed as a see-through image in the Z direction. The opening pattern BA301, the opening pattern BA302, and the opening pattern BA303 are arranged in order from the −X side to the +X side. The opening pattern BA301, the opening pattern BA302, and the opening pattern BA303 are separated from each other in the X direction.

Here, the maximum width of the groove pattern BA311 in the Y direction is narrower than the maximum widths of the opening patterns BA301, BA302, and BA303 in the Y direction. The maximum width of the groove pattern BA311 in the Y direction corresponds to the maximum width, in the Y direction, of a portion not overlapping the planar wiring lines MA1 to MA4 of the division pattern BA300 on the −Y side of the opening patterns BA301 to BA303. The maximum widths of the opening patterns BA301, BA302, and BA303 in the Y direction correspond to the maximum widths, in the Y direction, of the portions corresponding to the contact plugs CC overlapping the planar wiring lines MA1, MA3, and MA4 on the +Y side of the opening patterns BA301 to BA303. That is, the division pattern BA300 is formed such that the maximum width, in the Y direction, of the portion not overlapping the planar wiring line MA on the −Y side of each of the opening patterns BA301 to BA303 is narrower than the maximum width, in the Y direction, of the portion corresponding to the contact plug CC and overlapping the planar wiring line MA on the −Y side of each of the opening patterns BA301 to BA303.

Similarly, the maximum width of the groove pattern BA312 in the Y direction is narrower than the maximum widths of the opening patterns BA301, BA302, and BA303 in the Y direction. The maximum width of the groove pattern BA312 in the Y direction corresponds to the maximum width, in the Y direction, of a portion not overlapping the planar wiring lines MA1 to MA4 of the division pattern BA300 on the +Y side of the opening patterns BA301 to BA303. The maximum widths of the opening patterns BA301, BA302, and BA303 in the Y direction correspond to the maximum widths, in the Y direction, of the portions corresponding to the contact plugs CC overlapping the planar wiring lines MA1, MA3, and MA4 on the +Y side of the opening patterns BA301 to BA303. That is, the division pattern BA300 is formed such that the maximum width, in the Y direction, of the portion not overlapping the planar wiring line MA on the +Y side of each of the opening patterns BA301 to BA303 is narrower than the maximum width, in the Y direction, of the portion corresponding to the contact plug CC and overlapping the planar wiring line MA on the +Y side of each of the opening patterns BA301 to BA303.

As described above, in the fourth embodiment, the semiconductor memory device 301 has a configuration in which the maximum width, in the Y direction, of the portion not overlapping the planar wiring lines MA1 to MA4 of the division pattern BA300 is narrower than the maximum width, in the Y direction, of the portion overlapping the planar wiring lines MA1, MA3, and MA4 and corresponding to the contact plug CC. With this configuration, it is possible to suppress formation of a step on the main surface on the +Z side of the interlayer insulating film DL303 at the XY position between the plurality of planar wiring lines MA, leading to achievement of a layout configuration capable of suppressing occurrence of a pattern defect such as a conductive film residue between the plurality of planar wiring lines MA at the time of forming the planar wiring line MA. That is, it is possible to optimize the layout configuration in the chip 20 located at the uppermost portion in the structure in which the plurality of chips 10 and 20 are stacked.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first chip extending in a first direction and a second direction intersecting the first direction;
a second chip extending in the first direction and the second direction and bonded to the first chip in a third direction intersecting the first direction and the second direction,
wherein the first chip includes:
a first stacked body including a stack of a plurality of first conductive layers, each of the first conductive layers being stacked on each other via a first insulating layer;
a first semiconductor film extending in the third direction within the first stacked body;
a second stacked body adjacent to the first stacked body in the second direction and having a stack of a plurality of second conductive layers, each of the second conductive layers being stacked on each other via a second insulating layer;
a second semiconductor film extending in the third direction within the second stacked body;
a contact plug extending in the third direction between the first stacked body and the second stacked body; and
a first planar wiring line disposed on a side opposite to the second chip with respect to the first stacked body, the contact plug, and the second stacked body, the first planar wiring line extending in the first direction and the second direction, covering at least the contact plug, and being connected to the contact plug.

2. The semiconductor memory device according to claim 1,
wherein the first chip further includes:
a third conductive layer covering the first stacked body and the second stacked body from a side opposite to the second chip and having a division pattern between the first stacked body and the second stacked body,
the division pattern, when viewed as a see-through image in the third direction, intersects the first planar wiring line and internally includes the contact plug at a position overlapping with the first planar wiring line, and
the division pattern is formed such that a maximum width, in the second direction, of a portion not overlapping the first planar wiring line is narrower than a maximum width, in the second direction, of a portion corresponding to the contact plug.

3. The semiconductor memory device according to claim 2,
wherein the first chip further includes
a second planar wiring line disposed on a side opposite to the second chip with respect to the first stacked body and the second stacked body, separated from the first planar wiring line in the first direction, extending in the first direction and the second direction, and covering the first stacked body and the second stacked body, and
the division pattern is formed such that a maximum width, in the second direction, of a portion located between the first planar wiring line and the second planar wiring line is narrower than a maximum width, in the second direction, of a portion covered with the first planar wiring line.

4. The semiconductor memory device according to claim 2, further comprising
an insulating film covering the first stacked body, the second stacked body, and the third conductive layer from a side opposite to the second chip, the insulating film being provided with an opening pattern included inside the division pattern and internally including the contact plug when viewed as a see-through image in the third direction,
wherein the division pattern is formed such that a maximum width, in the second direction, of a portion not overlapping the first planar wiring line is narrower than a maximum width of the opening pattern in the second direction.

5. The semiconductor memory device according to claim 2, further comprising
an insulating film covering the first stacked body, the second stacked body, and the third conductive layer from a side opposite to the second chip, the insulating film being provided with an opening pattern included inside the division pattern and internally including the contact plug when viewed as a see-through image in the third direction, and
the division pattern does not include the opening pattern of the insulating film at a portion not overlapping the first planar wiring line when viewed as a see-through image in the third direction.

6. The semiconductor memory device according to claim 2,
wherein the division pattern includes:
a first opening pattern that, when viewed as a see-through image in the third direction, internally includes the contact plug and has a first maximum width in the second direction; and
a first groove pattern that, when viewed as a see-through image in the third direction, does not include the contact plug, the first groove pattern being adjacent to the first opening pattern in the first direction, and having a second maximum width narrower than the first maximum width in the second direction.

7. The semiconductor memory device according to claim 6,
wherein an arrangement position of the first groove pattern in the second direction corresponds to a center of the first opening pattern in the second direction.

8. The semiconductor memory device according to claim 6,
wherein an arrangement position of the first groove pattern in the second direction corresponds to a position shifted from a center of the first opening pattern in the second direction.

9. The semiconductor memory device according to claim 6,
wherein the division pattern further includes
a second groove pattern that does not include the contact plug, the second groove pattern being adjacent to the first opening pattern on an opposite side of the first groove pattern in the first direction, and having a third maximum width narrower than the first maximum width in the second direction.

10. The semiconductor memory device according to claim 6, further comprising
an insulating film covering the first stacked body, the second stacked body, and the third conductive layer from a side opposite to the second chip, the insulating film, when viewed as a see-through image in the third direction, having a second opening pattern that overlaps the first opening pattern and internally includes the contact plug,
wherein a maximum width, in the second direction, of the first groove pattern in the second direction is narrower than a maximum width, in the second direction, of the second opening pattern in the second direction.

11. The semiconductor memory device according to claim 9
wherein the second opening pattern internally includes the first opening pattern when viewed as a see-through image in the third direction.

12. The semiconductor memory device according to claim 2,
wherein a main surface of the insulating film on a side opposite to the second chip has a step larger than a film thickness of the third conductive layer at a position overlapping the first planar wiring line when viewed as a see-through image in the third direction.

13. The semiconductor memory device according to claim 2,
wherein a main surface of the first planar wiring line on a side opposite to the second chip has a step larger than a film thickness of the third conductive layer.

14. The semiconductor memory device according to claim 4,
wherein a main surface of the insulating film on a side opposite to the second chip is either a flat portion or has a step smaller than a film thickness of the third conductive layer at a position not overlapping the first planar wiring line when viewed as a see-through image in the third direction.

15. The semiconductor memory device according to claim 5,
wherein a main surface of the insulating film on a side opposite to the second chip is either a flat portion or has a step smaller than a film thickness of the third conductive layer at a position not overlapping the first planar wiring line when viewed as a see-through image in the third direction.

16. The semiconductor memory device according to claim 6,
wherein, when viewed as a see-through image in the third direction, a main surface of the first planar wiring line on a side opposite to the second chip has a step larger than a film thickness of the third conductive layer at a portion overlapping the first opening pattern and is either a flat portion or has a step smaller than the film thickness of the third conductive layer at a portion overlapping the first groove pattern.

17. The semiconductor memory device according to claim 6,
wherein, when viewed as a see-through image in the third direction, a main surface of the insulating film on a side opposite to the second chip has a step larger than a film thickness of the third conductive layer at a portion overlapping the first opening pattern and is either a flat portion or has a step smaller than the film thickness of the third conductive layer at a portion overlapping the first groove pattern.

18. The semiconductor memory device according to claim 1,
wherein the contact plug reaches an inside of the first planar wiring line.

19. The semiconductor memory device according to claim 1,
wherein a width of the first planar wiring line in the first direction is wider than a width of the contact plug in the first direction.

20. The semiconductor memory device according to claim 1,
wherein the first chip includes a first electrode, and
the second chip includes a second electrode bonded to the first electrode.
